(19) United States
(12) Patent Application Publication
(10) Pub. No.: US 2007/0023702 A1
(43) Pub. Date: Feb. 1, 2007

(54) METHOD FOR MANUFACTURING A MASK AND AN ORGANIC EL ELEMENT AND AN ORGANIC EL PRINTER

(75) Inventor: Shinichi YOTSUYA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/427,039

(22) Filed: Jun. 28, 2006

(30) Foreign Application Priority Data
Jul. 27, 2005 (JP) 2005-216871

(51) Int. Cl. G21K 5/10

(52) U.S. Cl. 250/492.22

(57) ABSTRACT

A mask for the use of an etching process for forming a film on a subject film deposition substrate into a predetermined pattern includes a protection section for covering the film on a pattern area to be formed into the pattern, and a projecting section provided on a facing surface so as to project therefrom, with the facing surface facing to the subject film deposition substrate of the protection section at a position corresponding to a peripheral section of the pattern area.

### BACKGROUND

1. Technical Field

The invention relates to a method for manufacturing a mask and an organic EL element and an organic EL printer. The invention specifically relates to a mask to be used in a dry etching process in order to form a high polymer organic EL element.

2. Related Art

An organic EL panel having a plurality of thin layers laminated one another and of selfluminous has been watched as a light source since such panel can be manufactured with ease.

The high polymer organic EL element can be formed in the atmosphere in such a manner that the high polymer organic EL material is dissolved in a solvent to be subjected to a spin-coating method or an ink jet method, resulting in enabling to manufacture a large substrate with ease. The spin-coating method is frequently used upon forming monochromatic light sources or illuminations for the reason of easy manufacturing thereof.

However, in the spin-coating method, the organic material is applied over an application surface of the substrate. Thus, the organic material has to be removed selectively by using the solvent or the like when opening windows for establishing electric connections with sealed portions, circuits or the like. A large amount of solvent has been sprayed onto a peripheral section of the substrate in order to dissolve and remove the organic material. However, such method consumes a large amount of solvent, resulting in a large amount of waste solution, and therefore raising a concern as to an adverse effect to a global environment.

It is conceivable to employ the following method in order to resolve the above stated problem.

Namely, the organic material is applied onto the substrate to form a film by the spin-coating method and a mask having an opening area corresponding to a pattern is sealed over the substrate. Then, an unnecessary portion of the film where the mask does not cover is selectively removed by a dry etching process using oxygen plasma gas to finally form the predetermined pattern on the substrate. See, JP-A-2005-166476.

According to the above stated method, an accurate patterning can be achieved by the mask without requiring a large amount of solvent. As such, an extra area necessary for an invasion of the solvent can be reduced, thereby realizing a downsizing of a chip as a final product. Such a downsizing involves an increase of the number of chips made from a sheet of substrate, which achieves lowering of a cost of each chip.

### SUMMARY

However, according to the method as disclosed in the JP-A-2005-166476, a facing surface, i.e., a mounting surface, of the mask facing to the substrate is brought into contact with the organic material on the substrate, thereby selectively performing an etching process to the organic material of an area where the mask does not cover, when the organic material formed into a film over the substrate is formed into a predetermined pattern. Consequently, a surface of the light emitting layer which is formed into a pattern is brought into contact with a facing surface of the mask, which raises a problem of suffering a damage such as bruises due to the contact with the mask.

An advantage of some aspects of the invention is to provide a mask capable of forming a pattern without a damage due to bruises or the like upon formation of a predetermined shaped pattern via a mask etching process and to provide a high polymer organic EL light emitting element of high accuracy with ease by using the aforementioned mask.

According to an aspect of the invention, the mask used in etching process for forming the film formed on the subject film deposition substrate into the predetermined pattern includes a protection section for covering at least the film of a pattern area to be formed into the predetermined pattern, and a projecting section projecting from the facing surface of the protection section, which faces to the subject film deposition substrate, and being at a position corresponding to a peripheral section of the pattern area.

With such a structure as stated above, the projecting section projecting from the facing surface of the protection section of the mask contacts the film formed on the subject film deposition substrate upon forming the film into the predetermined pattern. Here, the projecting section is arranged at the position corresponding to a peripheral section of the pattern area, and therefore the area of the film the projecting section contacts is an area of the film on which no pattern is formed. On the other hand, the protection section is supported by the projecting section projecting from the facing surface thereof, such that the facing surface of the protection section does not contact the film formed on the subject film deposition substrate. In other words, the film corresponding to the pattern area does not contact the protection section. That is, the film corresponding to the pattern area does not contact the mask, and therefore the possible damage of the film caused by the contact by the mask can be prevented.

Also, if the patterning of the film is performed by, for example, a plasma etching process or the like, the projecting section provided on the facing surface of the protection section of the mask takes a role of a barrier, such that an invasion of plasma gas from a side of the mask can be prevented. Thus, the accurate patterning can be achieved.

It is preferable for the mask according to the invention that the projecting section is formed so as to define the peripheral edge of the facing surface of the protection section.

With such a structure, the projecting section is formed so as to define the peripheral edge of the facing surface of the protection section, such that the projecting section serves as the barrier for preventing plasma gas from invading from the side of the mask upon etching process such as a plasma etching process. As such, plasma gas can be restrained from coming around during the etching process, such that an extremely precise pattern can be formed. An area of the film immediately below the area in contact with the projecting section of the mask is the film of the area where no pattern is formed. However, an adjustment of time period for performing the etching process and the like can control the coming around of the plasma gas, such that the film immediately below the area of the projecting section can be removed with ease. As a result, the pattern of the predetermined shape can be formed while avoiding the damage of the pattern area. Further, since the projecting section is formed at a position corresponding to the area on which no pattern is formed, the pattern will not be damaged even if the mask is brought into contact with the film.

It is preferable for the mask according to the invention that a plurality of protection sections are arranged so as to be bridged one another by beams.

According to such a structure that the plurality of protection sections are bridged one another by beams, an integral mask composed of a plurality of protection sections is built. Accordingly, patterning of a plurality of patterns can be achieved at one time, thereby being capable of realizing a reduced time for forming a pattern and a cost-down of the resulting product.

It is preferable for the mask according to the invention that a frame section for supporting the protection sections is arranged along an outer periphery of the plurality of the protection sections, the protection sections and the frame section are bridged each other by the beams, a thickness of the frame section is thinner than a combined thickness of the protection section and the projecting section, and the frame section is bridged at a position oppositely apart from the facing surface of the projecting section, which faces to the subject film deposition substrate.

With such a structure, the mask is so formed that the outside is thinner than the inside and the frame section is bridged at the position apart from the facing surface of the protection section Therefore, at a time the protection section of the mask is brought into contact with the subject film deposition substrate, the frame section is still in the air. If the frame section in this condition is pressed, an entirety of the mask will be deformed due to the elasticity of the beams. As such, the protection section positioned at a center of the mask receives more force, which contributes to a better contact ability between the mask and the subject film deposition substrate. Notches provided on the beams will enhance the elasticity of the beams to realize a more better contact ability between the mask and the subject film deposition substrate.

It is preferable for the mask according to the invention that the beams are arranged on each of the side surfaces of the respective protection sections and the frame section and each beam is arranged at a position away from each facing surface of the respective protection sections and the frame section.

With this structure, the beams for bridging between the side surfaces of the protection sections and the frame section are arranged at positions away from the facing surfaces, i.e., from the subject film deposition substrate, respectively, such that the beams do not contact the subject film deposition substrate when the mask is brought into contact with the subject film deposition substrate. Further, clearances are formed between the beams and the surfaces of the subject film deposition substrate. Accordingly, plasma gas will come around under the beams in the etching process to enable patterning of the film of the areas where basically no pattern is formed.

It is preferable for the mask according to the invention that the beams are formed into cylindrical shapes.

With such shapes of the beams, for example, unlike square shaped beams, the plasma gas will not be blocked by edges of the beams. Therefore, coming around of the plasma gas upon plasma etching process is enhanced, resulting in an effective patterning of the film of the area immediately below the beams

It is preferable for the mask according to the invention that the protection sections, the beams and the frame section are made of non-magnetic opaque materials such as glass, silicon or aluminum.

These non-magnetic opaque materials are free of affecting a track of plasma gas during the plasma etching process. Accordingly, a pattern in accordance with values obtained in designing process can be formed.

According to an another aspect of the invention, a manufacturing method of the organic EL element is featured in that the subject film deposition substrate is applied with the high polymer organic EL material by spin-coating method to form a film, and the resulting film is subjected to a dry etching process with oxygen using the mask as described in any one of the claims 1 to 7 in order to form the film into the predetermined pattern to manufacture the organic EL element.

With this structure, the high polymer organic EL element can be produced with ease without using an expensive printing apparatus or ink jet device. Additionally, projecting section is provided on the facing surface of the protection section of the mask, so that the emission layer can be formed into the predetermined shape without contacting mask. Namely, protecting the emission layer from the possible damage due to bruises establishes a mask dry etching process of a good yield rate.

According to a further aspect of the invention, the organic EL printer is featured in having the substrate on which the organic EL element manufactured by the above stated manufacturing method is arranged, a micro lens arranged facing to the organic EL element of the substrate in order to have an emitted light from the organic EL element pass through the lens with a predetermined image formation magnification, and a photosensitive drum on which the emitted light coming out of the micro lens forms the image to be exposed to light.

Since the organic EL printer according to the invention performs patterning using the above stated mask, the organic EL element with less damage can be produced. Consequently, an organic EL printer of less irregular light emission and of high precision can be provided.

### BRIEF DESCRIPTION OF THE DRAWINGS

FIG. 1 is a perspective view illustrating a schematic structure of a top surface of a mask according to the invention.

FIG. 2 is a perspective view illustrating a schematic structure of an under surface of the mask of FIG. 1 according to the invention.

FIG. 3 is a cross sectional view taken along a line A-A′ of the mask of FIG. 1 according to the invention.

FIG. 4 is a cross sectional view illustrating a state that the mask of FIG. 1 is brought into contact with a subject film deposition substrate according to the invention.

FIGS. 5A to 5D are cross sectional views illustrating steps of manufacturing an organic EL device according to the invention.

FIG. 6 is a cross sectional view illustrating a diagram of a reactive ion etching system.

FIG. 7 is a perspective view illustrating a schematic structure of the organic EL printer according to the invention.

### DESCRIPTION OF EXEMPLARY EMBODIMENTS

Explained hereinafter are embodiments of the invention, referring to the drawings. Each member in each of the drawings for explanation is freely scaled case by case in order to make it visible.

Mask Structure

Mask structure of the embodiment will be initially explained below.

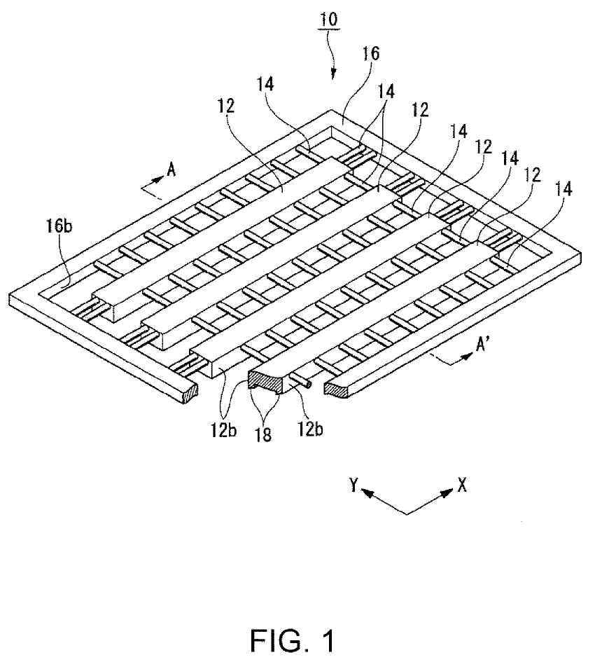

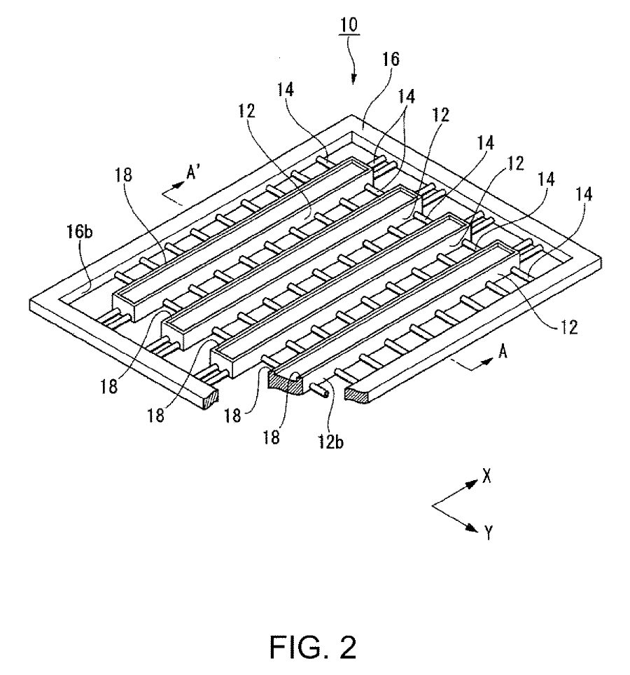

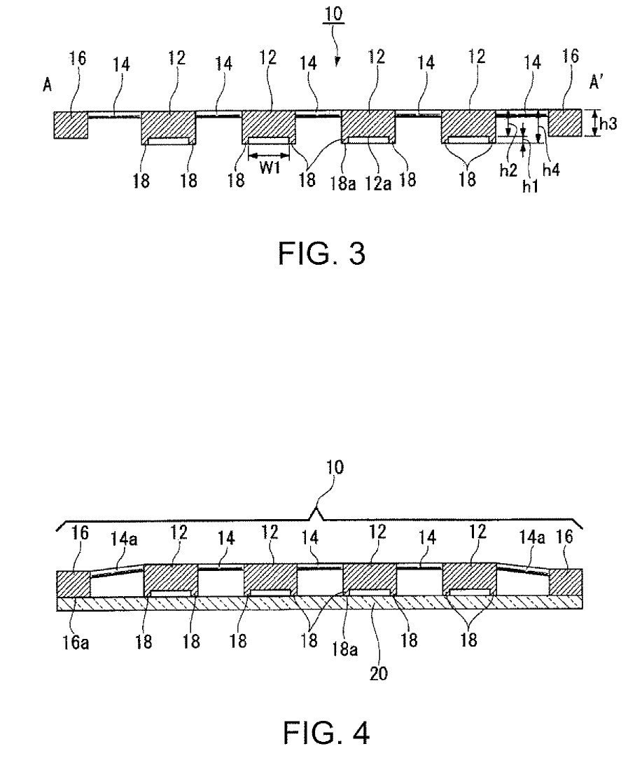

FIG. 1 is a perspective view showing a schematic structure of the mask 10 according to the embodiment. FIG. 2 is a cross-sectional view showing a schematic structure of an under side of the mask 10 as illustrated in FIG. 1. FIG. 3 is a cross-sectional view taken along a line A-A′ of the mask as illustrated in FIG. 1. FIG. 1 employs a x-y-z right-handed orthogonal coordinate system, in which a X-Y plane is in parallel with a surface of a paper and a Z plane is in vertical to the X-Y plane. Hatched portions are cut and removed portions of the mask in order to make them visible. In FIGS. 1 and 2, a under surface of the mask 10 which is indicated by an arrow is referred to as a facing surface since it is placed facing to the other substrate.

The mask 10 of the embodiment, as illustrated in FIG. 1, includes a plurality of protection sections or island sections 12 for covering a portion of film to be remained as a pattern, i.e., a pattern area, while the etching process or the like, a frame section or a peripheral frame 16 for forming an outer extent of the mask 10, and beams 14 for fixing the island sections 12 to each other and the island sections 12 and the peripheral frame 16 to each other, respectively.

The plurality of island sections 12, as illustrated in FIG. 1, are formed into elongated rectangular shapes and placed in such a manner longitudinal directions of the plurality of island sections 12 are in parallel with each other and spaced for a predetermined distance each other in Y-axis direction. The outer periphery of the plurality of island sections 12 is provided with a peripheral frame 16 in such a manner that the frame of a continuous rectangular shape encloses the plurality of island sections 12 in their entirety.

The beams are bridged in the Y-axis direction between opposed side surfaces 12b, 12b of the adjacent island sections 12, 12. The island sections 12, 12 are fixed to each other via the beams to finally form an integral island section composed of the plurality of island sections. The beams 14 are formed, for example, into cylindrical shapes and are mounted along with the longitudinal directions of the side surfaces 12b of the island sections 12 at even intervals. In a similar manner, side surfaces 16b of the peripheral frame 16 and the outer side surfaces 12b of the plurality of island sections 12 which faces to the peripheral frame 16 are bridged by the beams to fix the peripheral frame 16 and the island sections 12 to each other

Here, the beams 14 bridged between the side surfaces 12b of the island sections 12 and the side surfaces 16b of the peripheral frame 16, as mentioned below, should be mounted at positions where the beams would not contact the substrate, i.e., more particularly, a film formed on the substrate, in order to allow the plasma gas to come around below, i.e., to a contact surface side of, the beams 14 in FIG. 2. In other words, the beams 14, as shown in FIG. 3, are mounted to the upper positions of the side surfaces 12b of the island sections 12 and the side surfaces 16b of the peripheral frame 16. The beams 14 can be in any shapes such as square shapes other than the cylindrical shapes.

The facing surfaces 12a of the island sections 12, as shown in FIG. 2, is formed with projecting sections 18 in such a manner defining peripheral edges of the facing surfaces 12a. The projecting sections 18 are so formed that areas other than the peripheral edges of the facing surfaces 12a of the island sections 12 are concaved comparing to heights of the peripheral edges, thereby forming the projecting sections. As such, a side of each facing surface 12a of each island section 12 is formed into box shape having open upper surface. The island section 12 and the projecting section 18 are continuous.

Detailed explanation is given to the projecting sections 18 of the mask 10, referring to a cross sectional view of FIG. 3.

As seen from FIG. 3, formed at both ends of the facing surfaces 12a of the island sections 12, i.e., the peripheral edges of the facing surfaces 12a in FIG. 2, are projecting sections 18 projecting from the facing surfaces 12a by a height of h1. The contact surfaces 18a of the projecting sections 18 are formed generally in parallel with the facing surfaces 12a of the island sections 12. That is, in a deposition process as will be described later, contact surfaces 18a of the projecting sections 18 are generally in parallel with a surface direction of the substrate on which the mask is brought into contact. Accordingly, the projecting sections 18 can be brought into contact with the film on the substrate securely, thereby being capable of avoiding the invasion of the plasma gas. Shapes of the contact surfaces 18a of the projecting sections 18 may be formed so as to incline with respect to the facing surfaces 12a of the island sections 12 at a predetermined angle or may be curved as far as the contact surfaces 18a can contact the subject film deposition substrate.

According to the embodiment, a thickness h2 of each island section 12 generally equals to a thickness h3 of the peripheral frame 16. Therefore, a length h4 combining the height hi of each projecting section 18 and the thickness h2 of each island section 12 is longer than the thickness h3 of the peripheral frame 16.

A width w1 of each facing surface 12a of each island section 12 is defined so as to be equal to a length of a shorter side of the light emission layer, i.e., a pattern, composing a portion of the organic EL element as described later. That is, an area of each facing surface 12a of each island section 12 having the width w1 corresponds to a pattern area where a pattern is formed, and each contact surface 18a of each projecting section 15 corresponds to the area on which no pattern is formed.

The mask 10 according to the embodiment is formed into a shape as shown in FIGS. 1 to 3 using the same member, i.e., the same material, to form island sections 12, peripheral frame 16 and beams 14 bridged between the island sections and the peripheral frame. Preferable materials for the mask 10 have a resistance property against a dry etching process for ceramics or the like such as aluminum, silicon, aluminum oxide and have non-magnetic property as well. The material having the non-magnetic property is preferable because, if the material having the magnetic property is used, an uniform mask dry etching can not be performed since the density distribution of plasma gas generated during the dry etching process is disturbed by the magnetic property. In order to form a large mask for the use of a large substrate, it is suitable to form the mask 10 from aluminum.

When manufacturing the above stated mask 10, namely, when forming the mask 10 from aluminum, the mask 10 is shaved by a machining center to form the mask into the above stated shape. In the case of forming the mask 10 from silicon, an etching process using MEMS technique is employed to form the mask into the above stated shape. Further, in the case of forming the mask 10 from ceramics, a blasting process is employed to form the mask into the above stated shape.

Explained next is a cross sectional structure of the mask and a glass substrate when the mask according to the embodiment is actually mounted on the glass substrate, i.e. a subject film deposition substrate.

FIG. 4 is a cross sectional view illustrating a state that the mask 10 according to the embodiment is mounted on the glass substrate 20 on which a pattern is deposited. The explanation of the glass substrate will follow.

As shown in FIG. 4, the contact surface 16a of the peripheral frame 16 and the contact surfaces 18a of the projecting sections 18 are brought into contact with the glass substrate 20. Then, as stated above, the beams 14a bridged between the peripheral frame 16 and the outermost island sections 12 deflect since the projecting sections 18 project more than the contact surface 16a of the peripheral frame 16 and the facing surfaces 12a of the island sections 12. Because of the deflection of the beams 14, a pushing force applied to the peripheral frame 16 is transferred via the beams 14a and subsequently via the outermost island sections 12 to the island section 12 arranged at a center of an array of the island sections. In this manner, stronger pushing force is exerted to the island section 12 arranged at the center of the mask 10. Accordingly, the contact ability between the mask 10 and the glass substrate 20 is enhanced. Consequently, for example, as described later, oxygen radical gas or the like can be prevented from invading through a clearance between the mask 10 and the glass substrate 20 when irradiating oxygen plasma gas to the mask 10. The notches provided on the beams 14 can improve the elasticity of the beams 14.

According to the embodiment, since the film of the pattern area would not contact the mask 10 due to the projecting sections 18 serving as supporting members upon a formation of a pattern of the film, the possible damage of the film caused by a contact of the mask 10 can be prevented.

According to the embodiment, the projecting sections 18 are formed so as to define the peripheral edges of the facing surfaces 12a of the island sections 12, such that the projecting sections as barriers prevent the plasma gas from invading from a side of the mask 10 when performing the etching process, e.g., plasma etching process. Accordingly, the plasma gas is inhibited from coming around while performing etching process, and therefore a pattern of high precision can be formed. The film of the area immediately below the projecting sections 18 of the mask 10 is the film of the area on which no pattern is formed. However, an adjustment of a time period for performing the etching process or the like will enable an easy removal of the film of the area immediately below the projecting sections 18 because the plasma gas is inhibited from coming around. In this manner, while avoiding the possible damage of the pattern area, the predetermined pattern can be formed on the substrate.

According to the embodiment, the plurality of the island sections 12, 12 are bridged each other via beams 14, thereby forming the mask 10 composed of the plurality of island sections 12 formed into an integral section. Thanks to this structure, it becomes possible to form a plurality of patterns at the same time, which results in a shortened time period and a lower cost for forming patterns.

According to the embodiment, the mask 10 is made of the above stated non-magnetic opaque material, such that the track of the plasma gas is not adversely affected when performing the plasma etching process. Therefore, the pattern can be formed in accordance with the values obtained in the course of designing the pattern.

Manufacturing Method of Organic EL Device

Explained next is a process of manufacturing the organic EL device using the above stated mask.

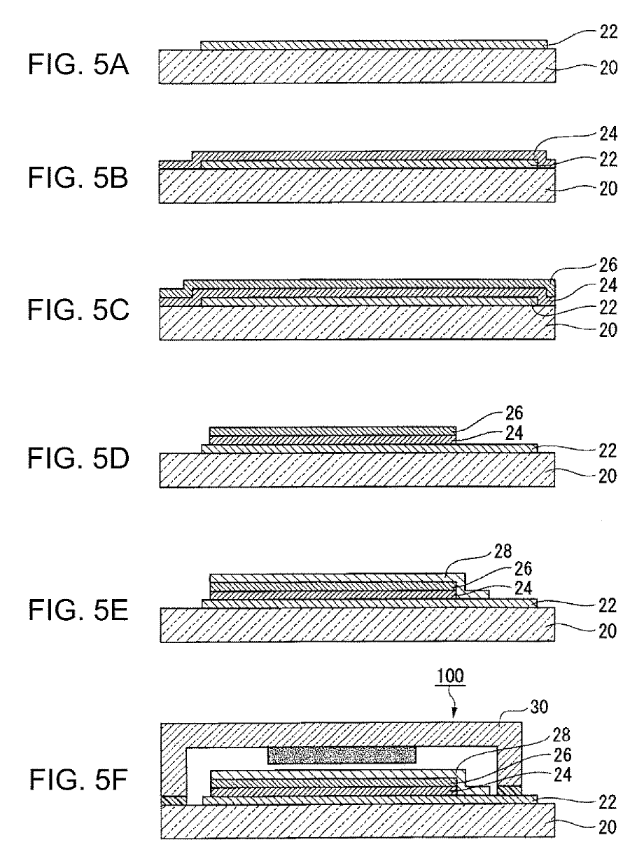

FIGS. 5A to 5F are cross sectional views illustrating the steps of manufacturing the organic EL device according to the embodiment.

As illustrated in FIG. 5A, the glass substrate 20 made of a transparent material is initially prepared to be formed with an positive electrode 22 thereon. The positive electrode 22 is formed by a mask deposition using ITO, i.e., an indium tin oxide, or IZO, i.e., an indium zinc oxide. After a formation of the positive electrode 22 on the glass substrate 20, ashing is performed using the oxygen plasma gas onto the surface of the glass substrate 20 together with the positive electrode 22, thereby cleaning the surface of the substrate.

Then, as illustrated in FIG. 5B, the positive electrode 22 is formed into a film and then a positive hole transportation layer 24 is formed thereon to cover the entire glass substrate 20. More specifically, the positive hole transportation layer 24 is formed into a film on the glass substrate 20 by a spin-coating method by dissolving a high polymeric material, e.g., styrene-sulfonate doped 3,4-polyethylenedioxythiophene/polystylene sulfonic acid (PEDOT/PSS) sold in the name of Bytron-p manufactured by Bayer AG in an amount 1.0 wt. % based on pure water. Then, the positive hole transportation layer 24 formed on the glass substrate 20 is subjected to a drying process by means of an nitrogen-purged oven at 120 degree centigrade for 10 minutes. As for the material for the positive hole transportation layer 24 other than the above, a mixture of polythiophene derivative such as polyethylenedioxythiophene and polystylene sulfonic acid or the like can be exemplified.

As shown in FIG. 5C, a light emission layer 26 is formed to cover positive hole transportation layer 24 in its entirety. More specifically, the light emission layer 26 is made such that a fluid in which PR212 manufactured by Covion Organic Semiconductors GmbH is dissolved in an amount 1 wt. % based on toluene is applied onto the glass substrate 20 by the spin-coating method. The light emission layer 26 formed on the glass substrate 20, then, is subjected to the drying process by means of an nitrogen-purged oven at 120 degree centigrade for 10 minutes. Suitable materials for the light emission layer 26 other than the above are polysilane polymers such as (poly) fluorine derivative (PP), (poly) para-phenylene vinylene derivative (PPV), polyphenylene derivative (PP), poly para-phenylene derivative (PPP), polyvinyl carbazole (PYK), polytiophene derivative and polymethylephenyl silane (PMPS).

As illustrated in FIG. 5D, the above stated mask 10 is mounted on a reactive ion etching system to be subjected to the dry etching process using oxygen plasma, thereby forming the positive hole transportation layer 24 and the light emission layer 26 into predetermined shaped patterns.

Here, a brief explanation is given to the above stated reactive ion etching system in the name of RIE-10NR manufactured by Samco Inc.

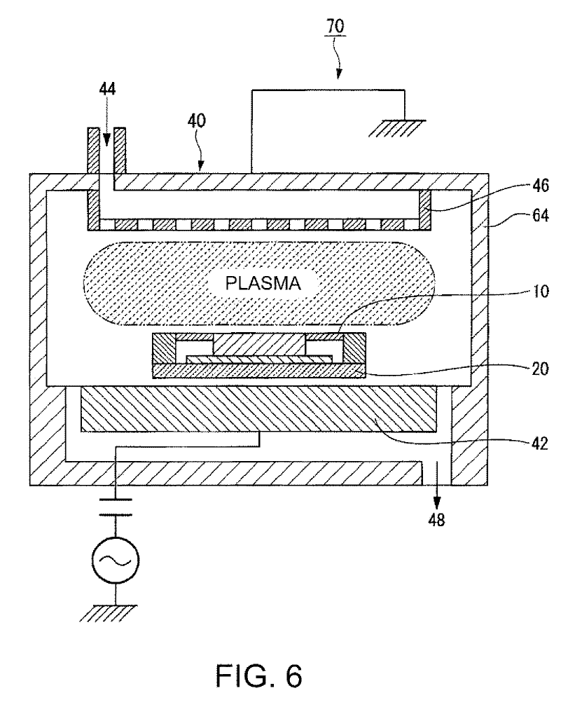

FIG. 6 is a cross sectional view illustrating a schematic view of the reactive ion etching system 70.

As shown in FIG. 6, provided with a container 64 of a chamber 40 at its upper section is a gas introduction port 44 for supplying gas to the chamber 40, and provided with the container 64 at its lower section is a gas discharging port 48 for discharging gas to an exterior of the chamber 40. A shower head 46 having a plurality of openings to be connected to the gas introduction port 44 is mounted to the upper section within the chamber 40, such that oxygen gas supplied from the gas introduction port 44 is irradiated within the chamber 40. A sample table 42 serving also as an electrode is provided at a lower section of the chamber 40. Placed on the sample table 42 is the glass substrate 20 on which the mask 10 is mounted. The sample table 42 also is connected to an exterior RF power source for the sake of applying bias. In this manner, the oxygen gas supplied to the chamber 40 is converted into plasma gas to perform the mask etching process.

According to the embodiment, the reactive ion etching system is specifically set to an etching rate of 0.4 μm/min. under the condition of 200 w of output power, 0.2 Torr of pressure and 30 sccm of a gas flow rate.

Now, turning back to FIG. 5D, the mask 10 according to the embodiment is mounted on the reactive ion etching system 70 under the above specified condition. Then, the positive hole transportation layer 24 and the light emission layer 26 formed on the glass substrate 20 are subjected to the dry etching process to form those layers into predetermined patterns. Here, the positive hole transportation layer 24 and the light emission layer 26 are subjected to the dry etching process at the same time; however such etching process may be separately given to the positive hole transportation layer 24 and the light emission layer 26. More specifically, the etching process can be given to the positive hole transportation layer 24 after it is formed into a film, and then given to the light emission layer 26 after it is formed into a film.

After the mask etching process, an negative electrode 28 is formed on the light emission layer 26 by using the mask 10 as shown in FIG. 5E. More specifically, calcium metal or the negative electrode 28 is deposited onto the light emission layer 26 for 1 nm, followed by a deposition of aluminum thereonto for approximately 150 nm. In FIG. 5E, it is illustrated as if the negative electrode 28 and the positive electrode 22 connect to each other; however, leader lines are actually formed at positions where they are not superimposed each other in the plane in order to be connected to predetermined terminals.

As shown in FIG. 5F, a sealing substrate or a sealing glass 30 seals the light emission layer 26 and the others in order to protect the light emission layer 26 and the others from humidity and oxygen. In this sealing process, the sealing glass 30 and the glass substrate 20 are sealed with bonding material while drying agent is inserted into the sealing glass 30. It is preferable for the sealing process to be performed in an atmosphere of an inert gas such as nitrogen, argon and helium. If the process is performed in the air, the negative electrode 28 may be oxidized due to an invasion of water, oxygen or the like.

In a process of applying the bonding material, the bonding material is applied in such a manner to enclose in the plane the light emission layer 26 to finally form a rectangular frame shape on an area where the positive hole transportation layer 24 and the light emission layer 26 were removed in a prior step. The bonding agent may be a photo-curable resin material or a heat-curable resin material, which, for example, can be applied by a printing method or the like.

A single color light emitting organic EL device 100 is obtainable through each of the above stated processes.

According to the embodiment, an area color, i.e., the single color emission type, high polymer organic EL element can be formed by the spin-coating method with ease, and a cost reduction can be achieved since an expensive ink jet printing apparatus is not necessary any more. Better flatness of a film to be formed on the substrate is obtainable in comparison with a case the light emission layer or the like is formed into a film by the ink jet printing apparatus. Further, since projecting sections 18 are provided on the facing surfaces 12a of the island sections 12 of the mask 10, the light emission layer can be formed into the predetermined pattern without contacting the mask. Consequently, by protecting the light emission layer from a damage of bluises, the mask dry etching process of good yield rate can be established.

Organic EL Printer

Explained hereinafter is an organic EL printer having the organic EL element manufactured using the above stated mask.

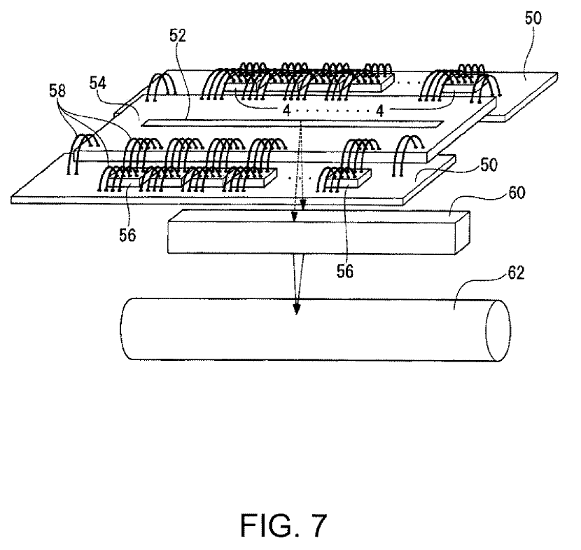

FIG. 7 is a diagram illustrating a schematic structure of the organic EL printer.

As shown in FIG. 7, the organic EL element 52 is arranged in line on a light emitting substrate 54. As stated above, the organic EL element 52 having the positive electrode, the positive hole transportation layer, the light emission layer and the negative electrode is configured to be a single color light emitting source. IC substrates 50 are arranged so as not to be superimposed by the organic EL element 52, below each of longer sides of the light emitting substrate 54. On the IC substrates 50, a plurality of driver ICs 56 are mounted corresponding to the number of pixels of the organic EL element 52 formed on the light emitting substrate 54. The organic EL element 52 and the driver ICs 56 are electrically connected to each other though wirings 58 by means of wire bonding. When driver ICs 56 is supplied with a predetermined data, current is fed to the positive electrode through the wirings 58. Accordingly, emitted light from the organic EL element 52 is irradiated toward a rear side, i.e., in a lower direction in FIG. 7, of the light emitting substrate 54. Arranged at the rear side, i.e., in a lower direction in FIG. 7, of the light emitting substrate 54 are a micro lens or a Selfoc™ lens array 60 and a photosensitive drum 62. The emitted light from the organic EL element 52 passes through an optical image system composed of an unmagnified imaging lens array such as the Selfoc lens array 60, and forms an image on the photosensitive drum 62 to be exposed to light.

According to the embodiment, ununiformity of light from the light source is less than that of LED printers, since the light source is not required to be mounted for each pixel. Further, since a pixel density can be increased up to 1200 dpi, it becomes possible to easily manufacture an extremely high speed and fine printer,

The invention is not limited to the above described examples, and it will be appreciated that various rearrangements and alterations may be made without departing from the spirit and scope of the invention. Also, the above described examples may be combined without departing from the spirit and scope of the invention.

For example, the thickness h4 of a combination of the thicknesses of the island section 12 and the projecting section 18 was different from the thickness h3 of the peripheral frame in the above described embodiment, however, it is appreciated that the thickness h4 of the combination of the thicknesses of the island section 12 and the projecting section 18 can be made generally equal to the thickness h3 of the peripheral frame.

Also, the projecting section 18 is formed as a part of the island section 12 by processing a part of the facing surface 12a of the island section 12 in the above described embodiment; however is not limited thereto. In other words, it is possible to arrange the projecting section 18 formed independently of the same material as or different material from the island section 12 along the peripheral edge of the facing surface 12a of the island section 12, for example, by means of bonding the projecting section 18 onto the facing surface 12a of the island section 12 via bonding agent

1. A mask used in an etching process for forming a film on a subject film deposition substrate into a predetermined pattern, the mask comprising:
a protection section for covering the film on a pattern area to be formed into the pattern; and
a projecting section projecting from a facing surface of the protection section facing to the subject film deposition substrate, the projecting section provided at a position corresponding to a peripheral section of the pattern area.

2. The mask according to claim 1, wherein the projecting section is formed so as to define the peripheral edge of the facing surface of the protection section.

3. The mask according to claim 1, further comprising a plurality of protection sections which are bridged each other by beams.

4. The mask according to claim 1, wherein a frame section for supporting the protection sections is provided along an outer periphery of the plurality of the protection sections; wherein the protection sections and the frame section are bridged through beams; and wherein a thickness of the frame section is thinner than a combined thickness of the protection section and the projecting section, and the frame section is bridged by beams at a position opposing to and away from the facing surface of the protection section facing to the subject film deposition substrate as well.

5. The mask according to claim 3, wherein the beams are provided on each of the side surfaces of the protection sections and the frame section; and wherein the beams are provided at positions away from each of the facing surfaces of the protection sections and the frame section.

6. The mask according to claim 3, wherein the beams are formed into cylindrical shapes.

7. The mask according to claim 1, wherein the protection sections, the beams and the frame section are made of non-magnetic opaque materials such as glass, silicon or aluminum.

8. A method for manufacturing an organic EL element comprising:
forming a film by applying a high polymer organic EL material onto a subject film deposition substrate by a spin-coating method; and
forming the film into a predetermined pattern through a dry etching process with oxygen using the mask according to claim 1 to produce an organic EL element.

9. An organic EL printer comprising:
a substrate on which the organic EL element manufactured by the manufacturing method according to claim 8 is arranged;
a micro lens, arranged so as to face to the organic EL element of the substrate, for allowing emitted light from the organic EL element to pass therethrough with a predetermined image forming magnification; and
a photosensitive drum on which the emitted light coming out of the micro lens is formed into an image to be exposed to light.
